(19) United States
(12) Patent Application Publication
(10) Pub. No.: US 2013/0192658 A1
(43) Pub. Date: Aug. 1, 2013

(54) SOLAR PANEL MODULE

(71) Applicants: Huang-Chi Tseng, Hsin-Chu (TW); Chiuan-Ting Li, Hsin-Chu (TW); Wei-Jieh Lee, Hsin-Chu (TW); Chun-Ming Yang, Hsin-Chu (TW); Kuan-Wen Tung, Hsin-Chu (TW); Ming-Yuan Huang, Hsin-Chu (TW); Zhen-Cheng Wu, Hsin-Chu (TW)

(72) Inventors: Huang-Chi Tseng, Hsin-Chu (TW); Chiuan-Ting Li, Hsin-Chu (TW); Wei-Jieh Lee, Hsin-Chu (TW); Chun-Ming Yang, Hsin-Chu (TW); Kuan-Wen Tung, Hsin-Chu (TW); Ming-Yuan Huang, Hsin-Chu (TW); Zhen-Cheng Wu, Hsin-Chu (TW)

(21) Appl. No.: 13/445,922

(22) Filed: Apr. 13, 2012

(30) Foreign Application Priority Data
Jan. 31, 2012 (TW) 101103042

(51) Int. Cl. H01L 31/052

(52) U.S. Cl. 136/246

(57) ABSTRACT

A solar panel module includes a solar panel, a supporting stand and a deflecting device. The supporting stand is structurally connected to the solar panel for supporting the solar panel. The solar panel is disposed inclinedly, and the solar panel has a tilt angle with respect to a horizontal plane. The deflecting device is disposed underneath the solar panel for deflecting wind blowing from lateral directions toward a wind exiting direction, which faces a bottom surface of the solar panel.

### BACKGROUND OF THE INVENTION

1. Field of the Invention

The present invention relates to a solar panel module, and more particularly, to a solar panel module having a solar panel with high heat dissipating efficiency and adjustable tilt angle.

2. Description of the Prior Art

Since petroleum resources on Earth are limited, the energy demands have shifted toward alternative energies dramatically in recently years. Among the alternative energy sources, solar energy shows the most promising potentials. In practical application, the power generating efficiency of solar panel is still limited due to some problems to be solved. First, the power generating efficiency of solar panel is generally inversely proportional to its operating temperature. That is to say, the higher the operating temperature of solar panel is, the lower the power generating efficiency is. Accordingly, even in the areas with sufficiency sunlight, the power generating efficiency would be adversely affected due to the environmental temperature changes and the temperature increase caused by substantially long-term power generation. In addition, the power generating efficiency is proportional to the amount of sunlight. However, the incident angle of sunlight in areas of different latitudes is different, and the incident angle varies at different time in a day because the rotation axis of Earth is tilted. Therefore, the solar panel module disposed in a stationary manner would suffer from low power generating efficiency because sunlight does not enter the solar panel perpendicularly at most of time.

### SUMMARY OF THE INVENTION

One of the objectives of the present invention is to provide a solar panel module having a solar panel with high heat dissipating efficiency and adjustable tilt angle.

According to a preferred embodiment, a solar panel module is provided. The solar panel module includes a solar panel, a supporting stand and a deflecting device. The supporting stand is structurally connected to the solar panel for supporting the solar panel. The solar panel is disposed inclinedly, and the solar panel has a tilt angle with respect to a horizontal plane. The deflecting device is disposed underneath the solar panel for deflecting wind blowing from lateral directions toward a wind exiting direction, which faces a bottom surface of the solar panel.

According to a preferred embodiment, a solar panel module is provided. The solar panel module includes a solar panel, at least two supporting stands and a deflecting device. The at least two supporting stands are placed under the solar panel and connected to the solar panel. The deflecting device is disposed underneath the solar panel and between the supporting stands, and the deflecting device has an opening facing to the solar panel.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams illustrating a solar panel module according to a first preferred embodiment of the present invention.

FIG. 3 and FIG. 4 are schematic diagrams illustrating a deflecting device of the solar panel module according to a first preferred configuration.

FIGS. 5-8 are schematic diagrams illustrating a deflecting device of the solar panel module according to a second preferred configuration.

FIGS. 9-12 are schematic diagrams illustrating a solar panel module according to a second preferred embodiment of the present invention.

### DETAILED DESCRIPTION

To provide a better understanding of the present invention to the skilled users in the technology of the present invention, preferred embodiments will be detailed as follows. The preferred embodiments of the present invention are illustrated in the accompanying drawings with numbered elements to elaborate the contents and effects to be achieved.

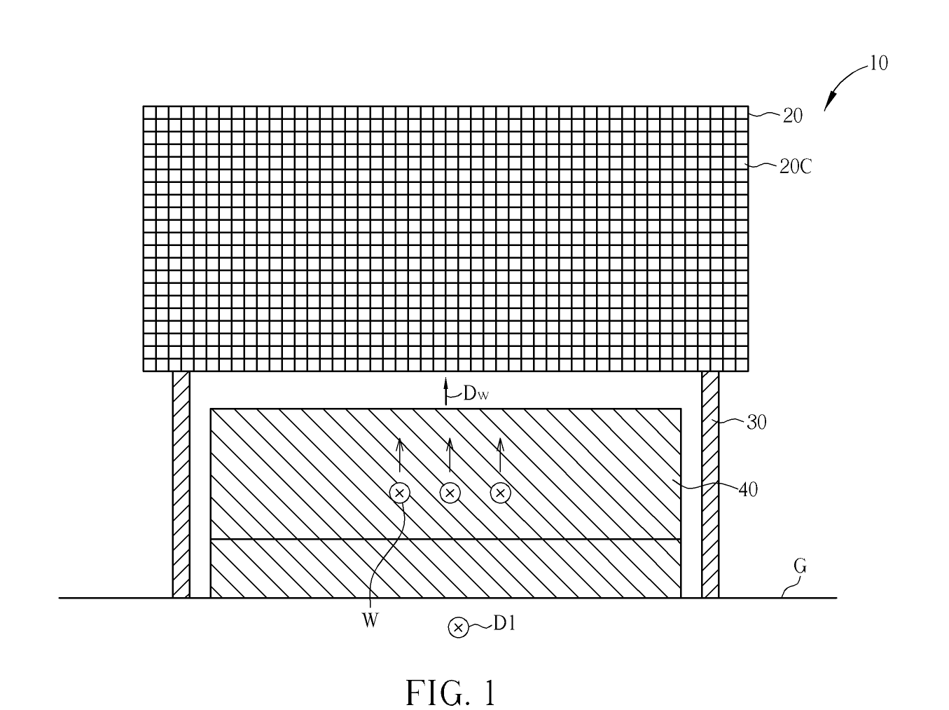

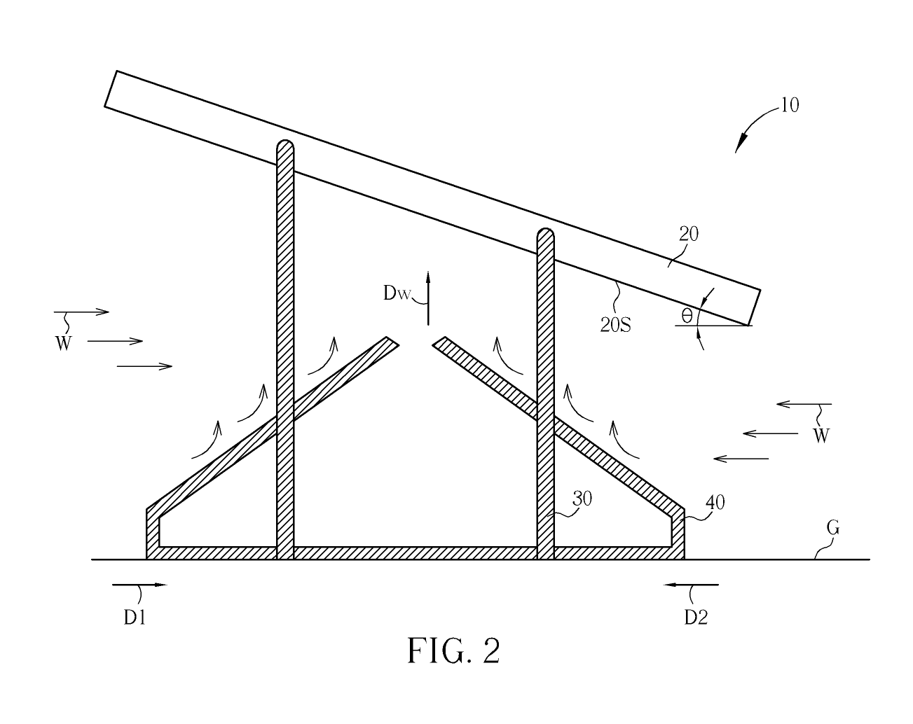

Please refer to FIG. 1 and FIG. 2. FIG. 1 and FIG. 2 are schematic diagrams illustrating a solar panel module according to a first preferred embodiment of the present invention, where FIG. 1 is a front view of the solar panel module, and FIG. 2 is a cross-sectional view of the solar panel module. As shown in FIG. 1 and FIG. 2, the solar panel module 10 of this embodiment includes a solar panel 20, a supporting stand 30 and a deflecting device 40. The solar panel 20 includes a plurality of solar cell units 20C. One end of the supporting stand 30 may be connected to the solar panel 20, while the other end of the solar supporting stand 30 may be disposed or fixed on the ground G or on the roof or wall of building for supporting the solar panel 20 and making the solar panel 20 dispose at a tilt angle θ with respect to the horizontal plane. The deflecting device 40 is disposed underneath the solar panel 20 for deflecting wind W blowing from lateral directions toward a wind exiting direction Dw facing a bottom surface 20S of the solar panel 20 to dissipate heat from the solar panel 20.

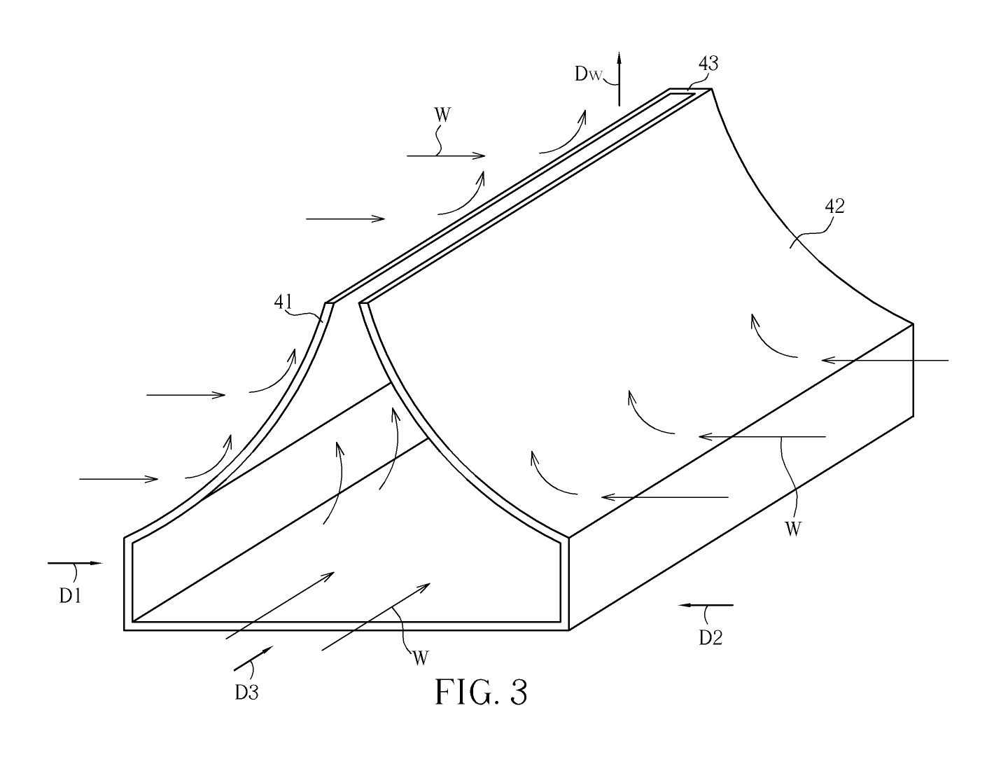

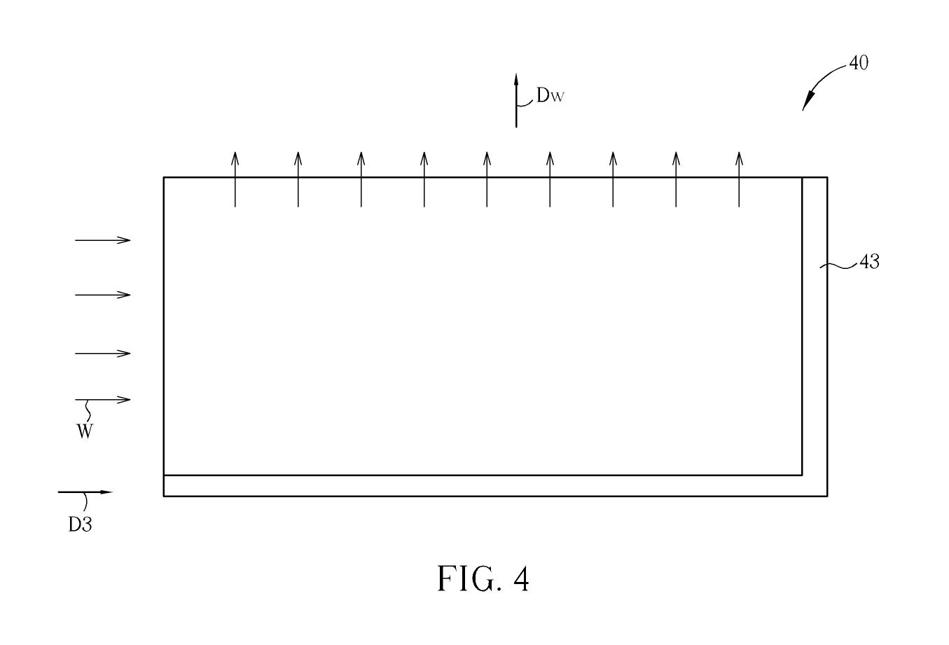

Please refer to FIG. 3 and FIG. 4, as well as FIG. 1 and FIG. 2. FIG. 3 and FIG. 4 are schematic diagrams illustrating a deflecting device of the solar panel module of FIG. 1 and FIG. 2 according to a first preferred configuration, where FIG. 3 is an oblique diagram of the deflecting device, and FIG. 4 is a cross-sectional view of the deflecting device. As shown in FIG. 3, the deflecting device 40 of the first configuration includes a first deflecting board 41 and a second deflecting board 42 disposed underneath the solar panel 20 and opposite to each other. The first deflecting board 41 and the second deflecting board 42 are used to deflect wind W blowing from a first lateral direction D1 toward the wind exiting direction Dw, and to deflect wind W blowing from a second lateral direction D2 opposite to the first lateral direction D1 toward the wind exiting direction Dw, respectively. At least one of the first deflecting board 41 and the second deflecting board 42 preferably has a curved surface for deflecting wind W blowing from the first lateral direction D1 and the second lateral direction D2 toward the wind exiting direction Dw, and the radius of curvature of the curved surface may be modified based on the requirement of deflecting effect. The first deflecting board 41 and/or the second deflecting board 42 are not limited to have curved surface, and may have an inclined surface for instance. In addition, as shown in FIG. 3 and FIG. 4, the deflecting device 40 may further include a third deflecting board 42 disposed underneath the solar panel 20 and between the first deflecting board 41 and the second deflecting board 42. The third deflecting board 43 is used to deflect wind W blowing from a third lateral direction D3 perpendicular to the first lateral direction Dl toward the wind exiting direction Dw.

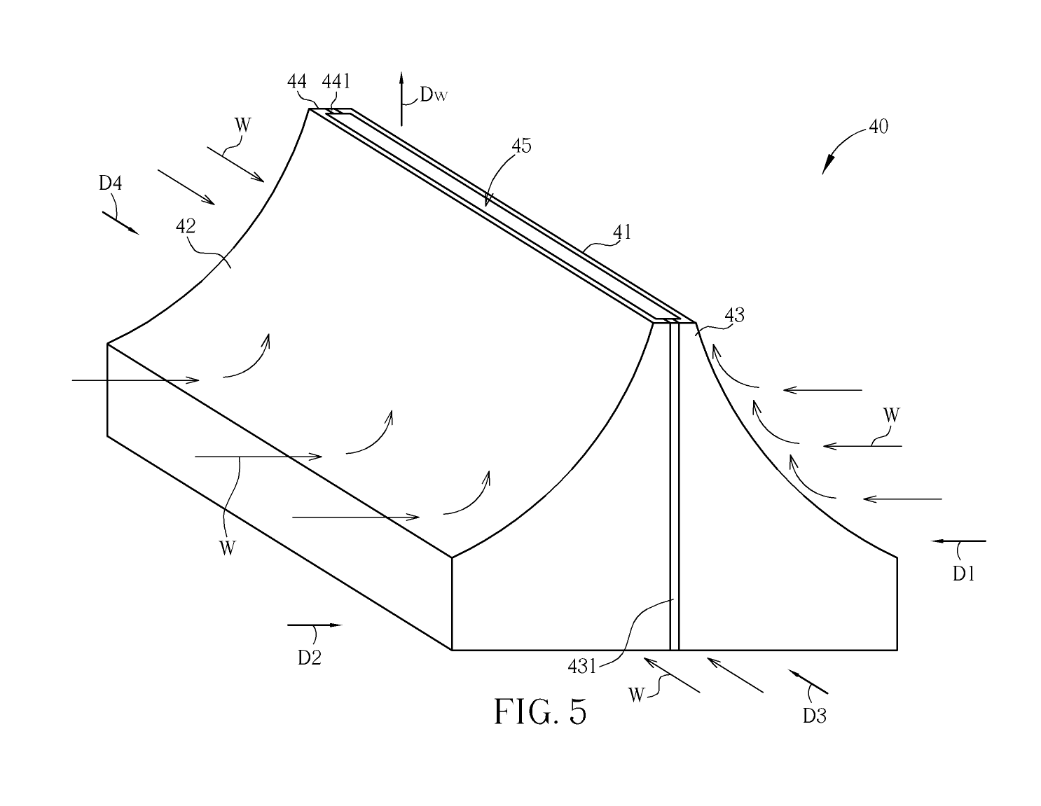

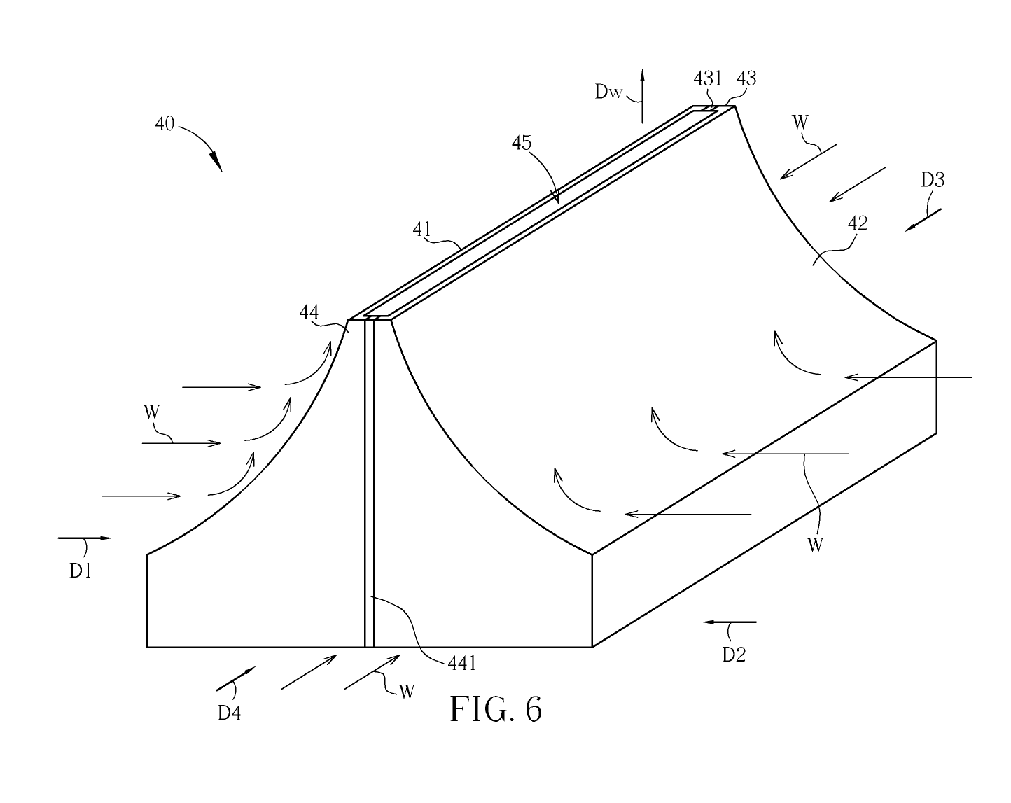

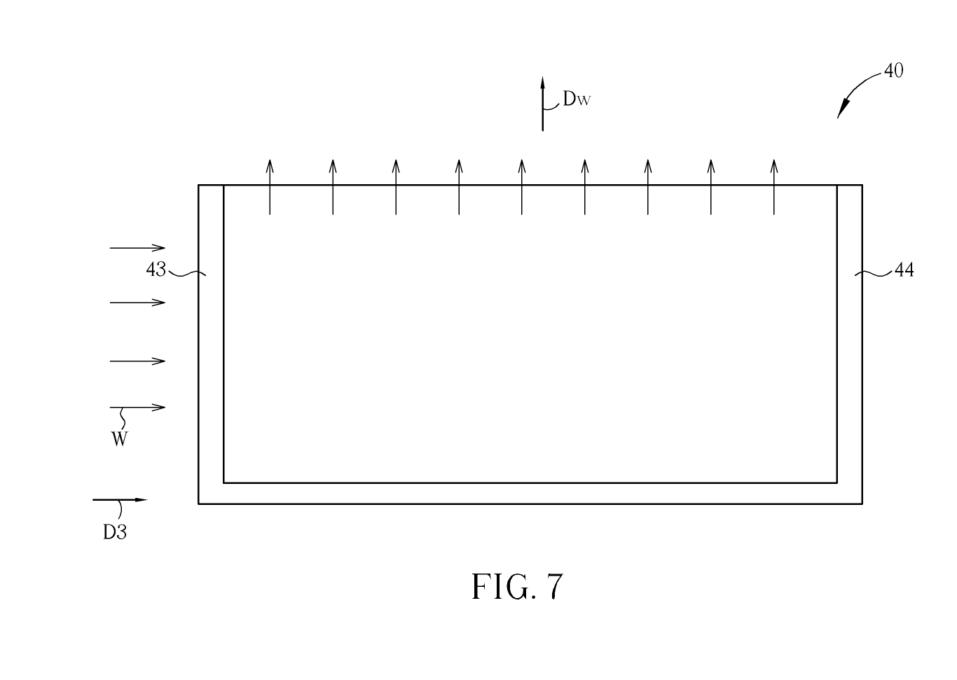

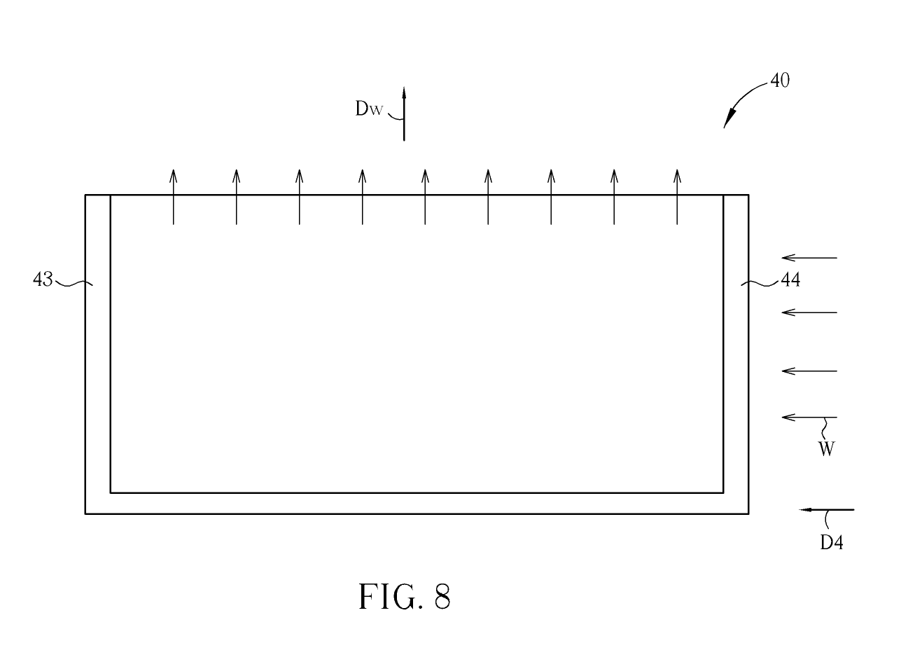

Please refer to FIGS. 5-8, as well as FIG. 1 and FIG. 2. FIGS. 5-8 are schematic diagrams illustrating a deflecting device of the solar panel module of FIG. 1 and FIG. 2 according to a second preferred configuration, where FIG. 5 and FIG. 6 are oblique views of the deflecting device, and FIG. 7 and FIG. 8 are cross-sectional views of the deflecting device. As shown in FIGS. 5-8, different from the first preferred configuration, in addition to the first deflecting board 41, the second deflecting board 42 and the third deflecting board 43, the deflecting device 40 of the second configuration further include a fourth deflecting board 44. The third deflecting board 43 and the fourth deflecting board 44 are disposed opposite to each other, and between the first deflecting board 41 and the second deflecting board 42. The first deflecting board 41, the second deflecting board 42, the third deflecting board 43 and the fourth deflecting board 44 form a space and an opening 45 facing the bottom surface 20S (as shown in FIG. 1) of the solar panel 20. The third deflecting board 43 is used to deflect wind W blowing from a third lateral direction D3 perpendicular to the first lateral direction D1 toward the wind exiting direction Dw, and the fourth deflecting board 44 is used to deflect wind W blowing from a fourth lateral direction D4 opposite to the third lateral direction D3 toward the wind exiting direction Dw. In the second configuration, the deflecting device 40 may further include a first check valve 431 disposed on the third deflecting board 43, and a second check valve 441 disposed on the fourth deflecting board 44. As shown in FIG. 5 and FIG. 7, the first check valve 431 allows wind W blowing from the third lateral direction D3 entering the space, and wind W entering the space through the first check valve 431 is deflected by the fourth deflecting board 44, and goes through the opening 45 toward the wind exiting direction Dw to dissipate heat from the solar panel 20. As shown in FIG. 6 and FIG. 8, the second check valve 441 allows wind W blowing from the fourth lateral direction D4 entering the space, and wind W entering the space through the second check valve 441 is deflected by the third deflecting board 43, and goes through the opening 45 toward the wind exiting direction Dw to dissipate heat from the solar panel 20.

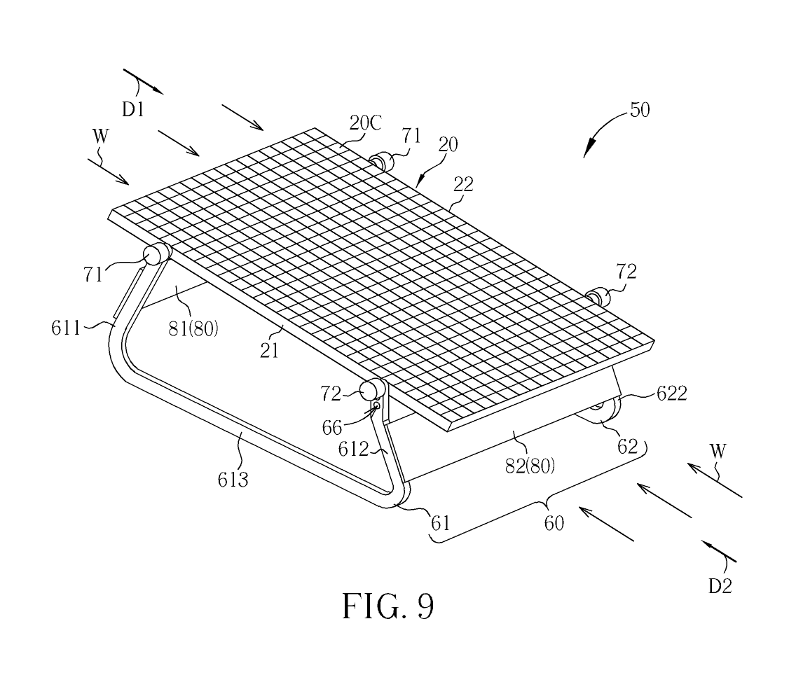

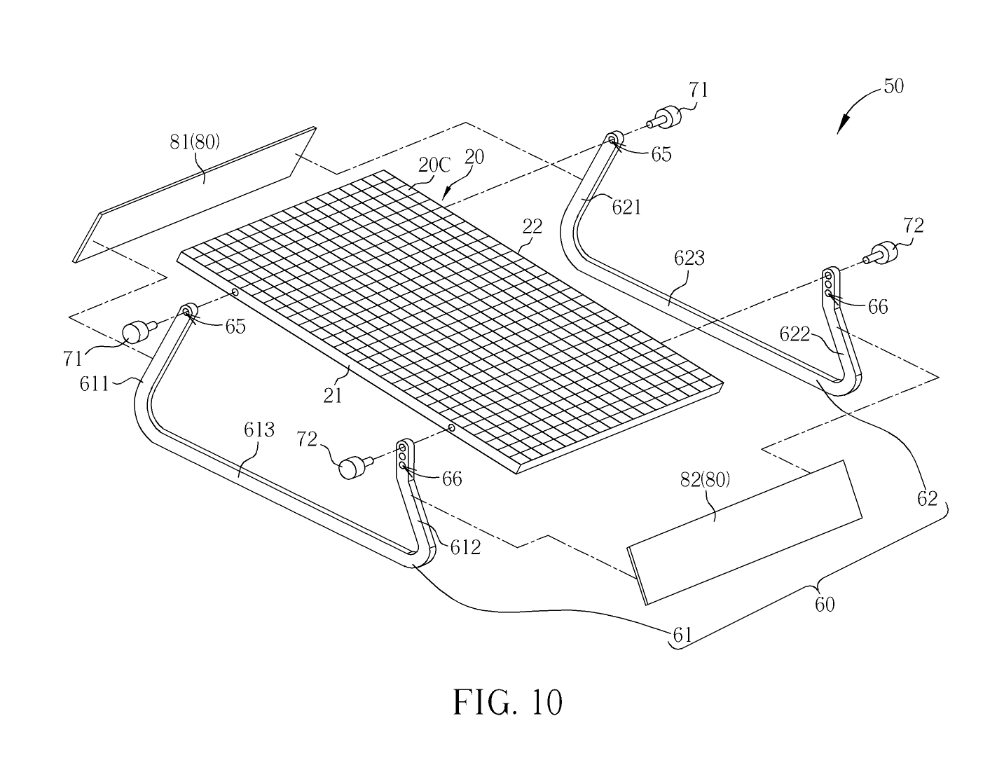

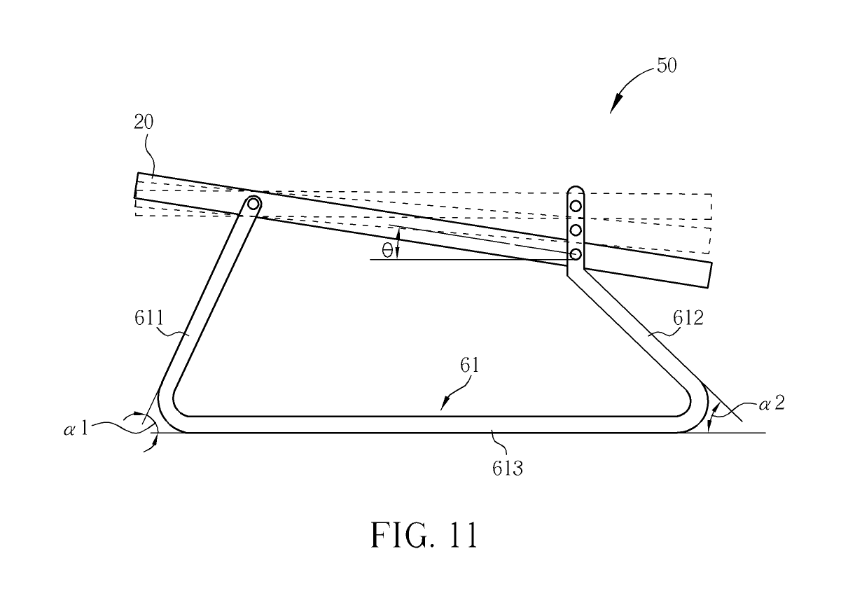

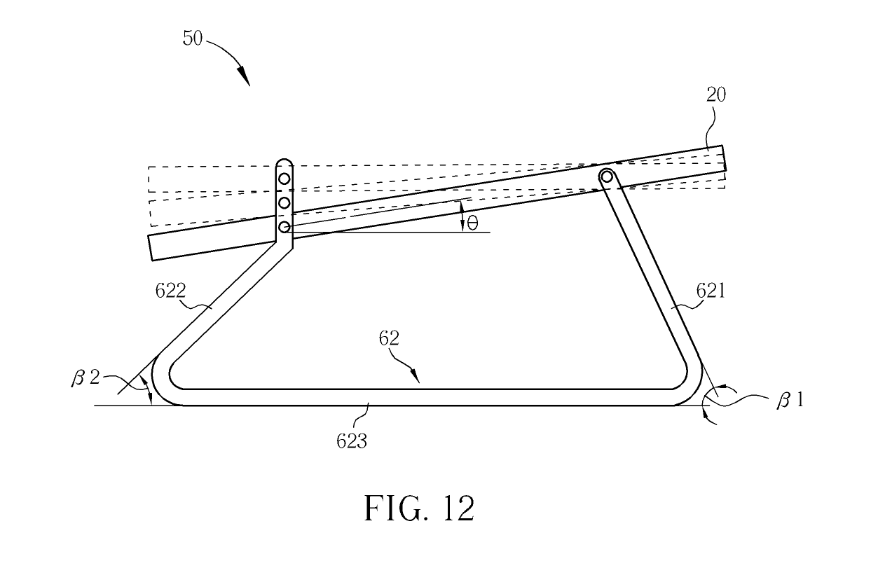

Please refer to FIGS. 9-12. FIGS. 9-12 are schematic diagrams illustrating a solar panel module according to a second preferred embodiment of the present invention, where FIG. 9 is an oblique view of the solar panel module, FIG. 10 is an exploded view of the solar panel module, FIG. 11 is a left side view of the solar panel module, and FIG. 12 is a right side view of the solar panel module. As shown in FIGS. 9-12, the solar panel module 50 of this embodiment includes a solar panel 20, a supporting stand 60 and a deflecting device 80. The solar panel 20 includes a plurality of solar cell units 20C, and the solar panel 20 has a first side 21 and a second side 22 disposed in parallel and opposite to each other. The supporting stand 60 includes a first frame 61 and a second frame 62. The first frame 61 includes a first part 611 connected to the first side 21 of the solar panel 20, and a second part 612 adjustably connected to the first side 21 of the solar panel 20 for adjusting the tilt angle θ of the solar panel 20. The second frame 62 includes a first part 621 connected to the second side 22 of the solar panel 20, and a second part 622 adjustably connected to the second side 22 of the solar panel 20 for adjusting the tilt angle 8 of the solar panel 20. In this embodiment, the first frame 61 may further include a third part 613 connected to the first part 611 and the second part 612 to form a U-shape like structure. The first part 611 and the third part 613 of the first frame 61 have an acute included angle α1, and the second part 612 and the third part 613 of the first frame 61 have an acute included angle α2. The second frame 62 may further include a third part 623 connected to the first part 621 and the second part 622 to form a U-shape like structure, the first part 621 and the third part 623 of the second frame 62 have an acute included angle β1, and the second part 622 and the third part 623 of the second frame 62 have an acute included angle β2. In this embodiment, the first frame 61 is preferably a monolithically-formed frame, and the second frame 62 is preferably a monolithically-formed frame, but not limited thereto. For example, the first frame 61 may be formed by a plurality of pieces, and the second frame 62 may be formed by a plurality of pieces.

The solar panel module 50 may further include a plurality of first fastening devices 71 and a plurality of second fastening devices 72. The first fastening devices 71 and the second fastening devices 72 may be, for example, screws or rivets, but not limited thereto. In addition, the first part 611 of the first frame 61 and the first part 621 of the second frame 62 have at least one first hole 65, respectively, and the second part 612 of the first frame 61 and the second part 622 of the second frame 62 have a plurality of second holes 66, respectively. The first fastening devices 71 can be inserted into the first holes 65 for connecting the first part 611 of the first frame 61 with the first side 21 of the solar panel 20, and for connecting the first part 621 of the second frame 62 with the second side 22 of the solar panel 20. The second fastening devices 72 can be selectively inserted into a portion of the second holes 66 for adjustably connecting the second part 612 of the first frame 61 with the first side 21 of the solar panel 20, and for adjustably connecting the second part 622 of the second frame 62 with the second side 22 of the solar panel 20. Specifically, in this embodiment, the second fastening devices 72 can be inserted into proper second holes 66 to adjust the tilt angle θ of the solar panel 20 based on different incident angle of sunlight for improving power generating efficiency.

The deflecting device 80 is disposed underneath the solar panel 20, and the deflecting device 80 includes a first deflecting board 81 and a second deflecting board 82. The first deflecting 81 is fixed on the first part 611 of the first frame 61 and the first part 621 of the second frame 62 for deflecting wind W blowing from the first lateral direction D1 toward the wind exiting direction Dw. The second deflecting board 82 is fixed on the second part 612 of the first frame 61 and the second part 622 of the second frame 62 for deflecting wind W blowing from the second lateral direction D2 opposite to the first lateral direction D1 toward the wind exiting direction Dw. In this embodiment, the first deflecting board 81 and the second deflecting board 82 may be, for example, wind-shielding cloth or canvas, but not limited thereto. The material of the first deflecting board 81 and the second deflecting board 82 may also be other soft or hard wind-shielding materials. It is noted that the supporting stand of the second preferred embodiment may also be used to support the solar panel of the first preferred embodiment.

In summary, the deflecting device of the solar panel module of the present invention is able to deflect wind blowing from lateral directions toward the bottom surface of solar panel, and thus heat dissipating efficiency of the solar panel module is dramatically improved. Accordingly, power generating efficiency can be maintained after long-term operation because the solar panel can be kept at proper operating temperature. In addition, the supporting stand of the solar panel module has adjustable tilt angle design, making it possible to adjust the tilt angle of the solar panel based on the incident angle of sunlight.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A solar panel module, comprising:
a solar panel;
a supporting stand, structurally connected to the solar panel, for supporting the solar panel, wherein the solar panel is disposed inclinedly, and the solar panel has a tilt angle with respect to a horizontal plane; and
a deflecting device, disposed underneath the solar panel, for deflecting wind blowing from lateral directions toward a wind exiting direction, wherein the wind exiting direction faces a bottom surface of the solar panel.

2. The solar panel module of claim 1, wherein the deflecting device comprises a first deflecting board and a second deflecting board disposed underneath the solar panel and opposite to each other, for deflecting wind blowing from a first lateral direction toward the wind exiting direction and deflecting wind blowing from a second lateral direction, opposite to the first lateral direction, toward the wind exiting direction, respectively.

3. The solar panel module of claim 2, wherein the deflecting device further comprises a third deflecting board, disposed underneath the solar panel and between the first deflecting board and the second deflecting board, for deflecting wind blowing from a third lateral direction, substantially perpendicular to the first lateral direction, toward the wind exiting direction.

4. The solar panel module of claim 2, wherein the deflecting device further comprises a third deflecting board and a fourth deflecting board, disposed underneath the solar panel, opposite to each other and between the first deflecting board and the second deflecting board, and the first deflecting board, the second deflecting board, the third deflecting board and the fourth deflecting board form a space and an opening facing the bottom surface of the solar panel.

5. The solar panel module of claim 4, wherein the third deflecting board is used to deflect wind blowing from a third lateral direction, substantially perpendicular to the first lateral direction, toward the wind exiting direction, and the fourth deflecting board is used to deflect wind blowing from a fourth lateral direction, opposite to the third lateral direction, toward the wind exiting direction.

6. The solar panel module of claim 4, wherein the deflecting device comprises a first check valve disposed on the third deflecting board, and a second check valve disposed on the fourth deflecting board, wherein the first check valve is used to allow wind blowing from the third lateral direction entering the space, and wind entering the space through the first check valve is deflected by the fourth deflecting board, and goes through the opening toward the wind exiting direction, the second check valve is used to allow wind blowing from the fourth lateral direction entering the space, and wind entering the space through the second check valve is deflected by the third deflecting board, and goes through the opening toward the wind exiting direction.

7. The solar panel module of claim 2, wherein at least one of the first deflecting board and the second deflecting board has a curved surface.

8. The solar panel module of claim 1, wherein the solar panel has a first side and a second side disposed in parallel and opposite to each other, the supporting stand comprises a first frame and a second frame, the first frame comprises a first part connected to the first side of the solar panel, and a second part adjustably connected to the first side of the solar panel for adjusting the tilt angle of the solar panel, the second frame includes a first part connected to the second side of the solar panel, and a second part adjustably connected to the second side of the solar panel for adjusting the tilt angle of the solar panel.

9. The solar panel module of claim 8, wherein the first frame further comprises a third part connected to the first part and the second part to form a U-shape like structure, the first part and the third part of the first frame have an acute included angle, and the second part and the third part of the first frame have an acute included angle, and wherein the second frame further comprises a third part connected to the first part and the second part to form a U-shape like structure, the first part and the third part of the second frame have an acute included angle, and the second part and the third part of the second frame have an acute included angle.

10. The solar panel module of claim 9, wherein the first frame is a monolithically-formed frame, and the second frame is a monolithically-formed frame.

11. The solar panel module of claim 8, further comprising a plurality of first fastening devices and a plurality of second fastening devices, wherein the first part of the first frame and the first part of the second frame have at least one first hole, respectively, the second part of the first frame and the second part of the second frame have a plurality of second holes, respectively, wherein the first fastening devices are inserted into the first holes for connecting the first part of the first frame with the first side of the solar panel, and for connecting the first part of the second frame with the second side of the solar panel, and the second fastening devices are selectively inserted into a portion of the second holes for adjustably connecting the second part of the first frame with the first side of the solar panel, and for adjustably connecting the second part of the second frame with the second side of the solar panel.

12. The solar panel module of claim 8, wherein the deflecting device comprises a first deflecting board and a second deflecting board, the first deflecting board is fixed on the first part of the first frame and the first part of the second frame for deflecting wind blowing from a first lateral direction toward the wind exiting direction, and the second deflecting board is fixed on the second part of the first frame and the second part of the second frame for deflecting wind blowing from a second lateral direction, opposite to the first lateral direction, toward the wind exiting direction.

13. The solar panel module of claim 8, wherein the deflecting device comprises a first deflecting board and a second deflecting board, the first deflecting board is fixed on the first part of the first frame and the second part of the first frame for deflecting wind blowing from a first lateral direction toward the wind exiting direction, and the second deflecting board is fixed on the first part of the second frame and the second part of the second frame for deflecting wind blowing from a second lateral direction, opposite to the first lateral direction, toward the wind exiting direction.

14. A solar panel module, comprising:
a solar panel;
at least two supporting stands, placed under the solar panel and connected to the solar panel; and
a deflecting device, disposed underneath the solar panel and between the supporting stands, wherein the deflecting device has an opening facing to the solar panel.

15. The solar panel module of claim 14, wherein the deflecting device comprises a first deflecting board and a second deflecting board disposed underneath the solar panel and opposite to each other.

16. The solar panel module of claim 15, wherein the deflecting device further comprises a third deflecting board, disposed underneath the solar panel and between the first deflecting board and the second deflecting board.

17. The solar panel module of claim 15, wherein the deflecting device further comprises a third deflecting board and a fourth deflecting board, disposed underneath the solar panel and between the first deflecting board and the second deflecting board, and the third deflecting board and fourth deflecting board are disposed opposite to each other.

18. The solar panel module of claim 17, wherein the deflecting device comprises a first check valve disposed on the third deflecting board, and a second check valve disposed on the fourth deflecting board.

19. The solar panel module of claim 15, wherein the deflecting device further comprises a first check valve, disposed underneath the solar panel and between the first deflecting board and the second deflecting board.

20. The solar panel module of claim 19, wherein the deflecting device further comprises a second check valve, disposed underneath the solar panel and opposite to the first check valve.
